(19) United States
(12) Patent Application Publication
(10) Pub. No.: US 2015/0303343 A1
(43) Pub. Date: Oct. 22, 2015

(54) BUILT-IN VERTICAL DOPING STRUCTURES FOR THE MONOLITHIC INTEGRATION OF TUNNEL JUNCTIONS IN PHOTOVOLTAIC STRUCTURES

(71) Applicant: MCMASTER UNIVERSITY, Hamilton (CA)

(72) Inventors: Rafael KLEIMAM, Hamilton (CA); Jingfeng YANG, Hamilton (CA)

(21) Appl. No.: 14/421,870

(22) PCT Filed: Aug. 15, 2013
(86) PCT No.: PCT/CA2013/050634

§ 371 Date: Feb. 16, 2015

Related U.S. Application Data
(60) Provisional application No. 61/683,886, filed on Aug. 16, 2012.

(51) Int. Cl. H01L 31/0687; H01L 31/065; H01L 31/18

(52) U.S. Cl. CPC H01L 31/0687; H01L 31/1864; H01L 31/065

(57) ABSTRACT

Photovoltaic semiconductor structures, photovoltaic base structures for forming tandem photovoltaic cells, and methods of fabrication thereof, are provided, in which at least one tunnel junction layer is integrally formed within a semiconductor substrate via a shallow diffusion doping process. In some embodiments, two tunnel junction layers are formed within a common semiconductor substrate having a photovoltaic homojunction therein, such as silicon or germanium, via a two-step shallow diffusion doping process. In other embodiments, a first tunnel junction layer is formed within a semiconductor substrate having a photovoltaic homojunction via a shallow diffusion doping process, while a second tunnel junction layer is formed by an epitaxial or other additive process. In other embodiments, photovoltaic semiconductor structures are provided having an emitter layer and a first tunnel junction layer formed as a composite layer having a graded profile within a semiconductor substrate.

### CROSS-REFERENCE TO RELATED APPLICATION

This application claims priority to U.S. Provisional Application No. 61/683,886, titled “BUILT-IN VERTICAL DOPING STRUCTURES FOR THE MONOLITHIC INTEGRATION OF TUNNEL JUNCTIONS ONTO SILICON SOLAR CELLS FOR MULTI-JUNCTION PHOTOVOLTAIC APPLICATIONS” and filed on Aug. 16, 2012, the entire contents of which is incorporated herein by reference.

### BACKGROUND

The present disclosure relates to photovoltaic devices and solar cells.

In order to utilize as much of the solar spectrum as possible for the purposes of energy conversion, multiple solar cells can be stacked together and the adjacent solar cells connected electrically in series and optically in parallel. Commercially available multi-junction solar cells are based on this approach, which requires the electrical connection of adjacent solar cells in series via a tunnel junction in monolithically grown multi-junction devices.

Tunnel junctions are designed to be comprised of degenerately doped layers with abrupt P-N junction interfaces. The dopant levels on both the P-type and N-type sides of the tunnel junction are sufficiently high that the energy level overlaps between the conduction band of the N-type and the valance band of the P-type regions, allowing for band to band tunneling, forming a low resistance, high conduction path between two adjacent solar cells, known as an Ohmic connection.

The technology of multi-junction solar cells has advanced significantly in recent years, achieving cell efficiency of over 40% at 500 suns (where 1 sun is defined as 100 mW/cm² and the spectrum approximates that of the sun and is usually further specified). These commercially available multi-junction cells use high bandgap materials such as InGaP and InGaAs grown on germanium (Ge) substrates. The Ge substrates are very expensive, while silicon (Si) substrates are substantially less costly. Based on modeling as in the published patent application WO2009082816A1 to R. N. Kleiman, et al., a tandem cell, which consists of a top solar cell (bandgap of 1.68 eV) on Si solar cell (bandgap of 1.12 eV), yields a similar theoretical maximum efficiency as the triple junction cells using Ge substrates. Therefore, silicon-based tandem cells have a definite advantage of lower substrate cost while possibly achieving similarly high efficiency as the Ge-based triple junction solar cells.

U.S. Pat. No. 4,017,332 to L. W. James reported a connecting medium between GaAs and InP layers via the dislocations which are generated from lattice-mismatch between them. The interfacial defects may form a low resistance Ohmic connection or substantial short circuit. However, the dislocations may not be confined at the interface only and thus potentially affect the performance of device layers.

U.S. Pat. No. 4,179,702 to M. F. Lamorte demonstrated a III-V based tunnel junction with highly doped N-type and P-type AlGaAs layers. This is believed to be the first patent which describes connecting two solar cells via tunneling using highly doped P-N junction layers.

US Patent 2008/0023059 to B. M. Basol describes the connection of two solar cells via a transparent conductor which has a minimum resistance such as ruthenium oxide with a thickness of 2 to 20 nm. The solar cells in this example were (Cd,Zn)Te or Cu(In,Ga)(S,Se)2 which are also known as CZT and CIGS, respectively. The interconnecting material should form Ohmic contacts to both solar cells.

Carmody et al. in “Single-crystal II-VI on Si single-junction and tandem solar cells,” Appl. Phys. Lett. Vol. 96, 153502 (2010) fabricated a CdTe-based solar cell grown epitaxially on a crystalline silicon solar cell. The CdZnTe and Si junctions were connected by a wide bandgap, II-VI based and highly doped tunnel junction grown on a Si cell. The efficiency of the tandem cell was 17%.

Dashiell, et al. in “Current-voltage characteristics of high current density silicon Esaki diodes grown by molecular beam epitaxy and the influence of thermal annealing,” IEEE Trans. on Elect. Devices, Vol. 47, No 9, pp 1707-1714, 2000 demonstrated the fabrication of silicon Esaki tunnel diodes with the growth of MBE and a rapid thermal annealing process. The authors investigated the effect of annealing temperature on the tunneling current. Molecular beam epitaxial (MBE) growth has the advantage of controlling the deposited amount precisely and therefore it is a very useful tool for complex material research studies. However it is a very expensive process and the precursor materials are expensive.

U.S. Pat. No. 8,344,242 to Fiorenza describes a multi-junction solar cell whereby the tunnel junction connecting a silicon subcell to an InGaAs subcell is formed in the silicon substrate via ion implantation. However, ion implantation is considered to have too low a throughput and too high a cost for large scale solar cell manufacturing.

Therefore, a new method of fabricating silicon tunnel junctions is needed that uses less costly materials and simpler processes.

Spin-on-dopant (SOD) materials are attractive for the fabrication of P-N junctions among researchers since the costs of materials and processes are less costly compared to other techniques. Usami, et al. in “Shallow-junction formation on silicon by rapid thermal diffusion of impurities from a spin-on source,” IEEE Trans. Electron Dev., Vol. 39, pp. 105-110, 1992 demonstrated the formation of shallow P-N junctions using spin-on-dopants (SOD) and rapid thermal processing (RTP). This process is vital for the formation of a tunnel junction since it requires degenerately doped and very thin layers, typically 10 to 300 nm. However, when the SOD material, especially for the boron dopant source, is in direct contact with the surface of a wafer, a residual layer is formed following the thermal treatment and is insoluble in hydrofluoric acid or any other acid. This residue can be detrimental to the performance of devices, especially if an epitaxial layer is grown on top of the diffused surface of the silicon wafer.

Wang, et al. in “Silicon tunnel diodes formed by proximity rapid thermal diffusion,” IEEE Electron Device Letters, Vo. 24, No. 2, pp. 93-95, 2003 demonstrated a fabrication method of silicon tunnel junctions successfully using SODs. The problem of residual layers was avoided by a non-contact approach between the SOD source and the device wafer, which can be described as the proximity diffusion method. The SOD was first applied to a dummy silicon wafer and the transfer of dopant vapor occurred from the SOD layer of the dummy wafer to the device silicon wafer. They were closely spaced during the rapid thermal annealing process.

### SUMMARY

Photovoltaic semiconductor structures, photovoltaic base structures for forming tandem photovoltaic cells, and methods of fabrication thereof, are provided, in which at least one tunnel junction layer is integrally formed within a semiconductor substrate via a shallow diffusion doping process. In some embodiments, two tunnel junction layers are formed within a common semiconductor substrate having a photovoltaic homojunction therein, such as silicon or germanium, via a two-step shallow diffusion doping process. In other embodiments, a first tunnel junction layer is formed within a semiconductor substrate having a photovoltaic homojunction via a shallow diffusion doping process, while a second tunnel junction layer is formed by an epitaxial or other additive process. In other embodiments, photovoltaic semiconductor structures are provided having an emitter layer and a first tunnel junction layer formed as a composite layer having a graded profile within a semiconductor substrate.

Accordingly, in a first aspect, there is provided a photovoltaic semiconductor structure, comprising:
a first doped semiconductor layer forming an absorber layer of a first photovoltaic homojunction;
a second doped semiconductor layer having a conductivity type opposite to that of said first doped semiconductor layer, wherein said second semiconductor layer is formed adjacent to said first semiconductor layer, such that said first doped semiconductor layer and said second doped semiconductor layer are formed from a common semiconductor material within a common semiconductor substrate, and wherein said second semiconductor layer comprises a dopant profile with a graded concentration, such that:
   a first portion of said second semiconductor layer, distal from said first semiconductor layer, is degenerately doped, thereby forming a first tunnel junction layer of a tunnel junction; and
   a second portion of said second semiconductor layer, proximal to said first semiconductor layer, has a dopant concentration suitable for forming an emitter layer of said first photovoltaic homojunction; and
a third doped semiconductor layer having a conductivity type opposite to that of said second doped semiconductor layer, wherein said third doped semiconductor layer is provided adjacent to said second semiconductor layer, and wherein said third semiconductor layer is degenerately doped, thereby forming a second tunnel junction layer of said tunnel junction.

In another aspect, there is provided a method of forming a photovoltaic semiconductor structure having a composite emitter and tunnel junction layer, the method comprising:

providing a moderately doped semiconductor substrate; and

employing shallow diffusion doping to degenerately dope a region beneath the surface of the semiconductor substrate, such that a composite layer is formed having a conductivity type opposite to that of the moderately doped semiconductor substrate, such that the composite layer comprises:
a first portion proximal to the surface of the semiconductor substrate, the first portion having a degenerately doped concentration suitable for forming a first layer of a tunnel junction; and
a second portion distal from the surface of the semiconductor substrate, the second portion having dopant concentration suitable for forming an emitter layer;

such that a photovoltaic homojunction is formed within the semiconductor substrate.

In another aspect, there is provided a method of forming a photovoltaic semiconductor structure, the method comprising:

providing a semiconductor substrate comprising an absorber layer and an emitter layer having a photovoltaic homojunction formed therebetween, wherein the emitter layer is formed proximal to a surface of the semiconductor substrate;

employing a first shallow diffusion doping step to degenerately dope a region proximal to the surface of the semiconductor substrate, the region having a conductivity type opposite to that of the emitter layer, such that a first tunnel junction layer with a degenerately doped concentration is formed below the surface of the semiconductor substrate; and

employing a second shallow diffusion doping step to degenerately dope a region proximal to the surface of the semiconductor substrate, the region having a conductivity type opposite to that of the first tunnel junction layer, such that a second tunnel junction layer with a degenerately doped concentration is formed below the surface of the semiconductor substrate and above the first tunnel junction layer;

thereby forming a tunnel junction within the semiconductor substrate between the first tunnel junction layer and the second tunnel junction layer.

In another aspect, there is provided a method of forming a photovoltaic semiconductor structure, the method comprising:

providing a semiconductor substrate comprising an absorber layer and an emitter layer having a photovoltaic homojunction formed therebetween, wherein the emitter layer is formed proximal to a surface of the semiconductor substrate;

employing a first shallow diffusion doping step to degenerately dope a region proximal to the surface of the semiconductor substrate, the region having a conductivity type opposite to that of the emitter layer, such that a first tunnel junction layer with a degenerately doped concentration is formed below the surface of the semiconductor substrate; and

forming a second tunnel junction layer on the semiconductor substrate by an epitaxial or other additive process, wherein the second tunnel junction layer is degenerately doped and has a conductivity type opposite to that of the first tunnel junction layer;

thereby forming a tunnel junction between the first tunnel junction layer and the second tunnel junction layer.

A further understanding of the functional and advantageous aspects of the disclosure can be realized by reference to the following detailed description and drawings.

### BRIEF DESCRIPTION OF THE DRAWINGS

Embodiments will now be described, by way of example only, with reference to the drawings, in which:

FIGS. 1(a)-(f) show device structures for the monolithic integration of tunnel junctions or portions thereof into a composite multi-junction photovoltaic device. FIG. 1(a) shows a general structure of a photovoltaic cell having a substrate with an integrated tunnel junction, with a top cell structure added above to form a multi-junction photovoltaic device. FIG. 1(b) shows a three layer doping structure within the base substrate comprising the two layers of the tunnel junction and the photovoltaic cell emitter. FIG. 1(c) shows a two layer doping structure within the base substrate, where the lower tunnel junction layer has been combined with the emitter. FIG. 1(d) shows a general structure having a substrate with an integrated lower tunnel junction layer, with an upper tunnel junction layer and top cell structure added above to form a multi-junction photovoltaic device. FIG. 1(e) shows a two layer doping structure integrated within the base substrate comprising the photovoltaic device emitter and the lower tunnel junction layer, with an upper tunnel junction layer added above to form a composite base photovoltaic device and tunnel junction. FIG. 1(f) shows a one layer doping structure integrated within the base substrate comprising a combined photovoltaic device emitter and lower tunnel junction layer, with an upper tunnel junction layer added above to form a composite base photovoltaic device and tunnel junction.

FIGS. 2(a)-(d) show a series of test structures for demonstrating the performance of tunnel junction structures and the improved performance based on their integration with a base photovoltaic cell. FIG. 2(a) shows a test structure for the photovoltaic cell with a tunnel junction on top. FIG. 2(b) shows a test structure for the photovoltaic cell without a tunnel junction on top. FIG. 2(c) shows a test structure of the mesa-etched tunnel junctions on a P-based Si photovoltaic cell. Metal contacts were formed on both the P₊₊ and N₊₊ sides of the tunnel junction in order to probe the tunnel junctions. FIG. 2(d) shows a test structure of the tunnel junction control sample, where tunnel junctions were fabricated on an N₊ Si substrate. Due to the low resistance of the N₊ substrate, the N₊₊ side of the tunnel junction was easily contacted though the back side of the substrate.

FIG. 3 shows illuminated I-V characteristics of the fabricated photovoltaic cells with and without integrated tunnel junctions.

FIG. 4 shows I-V characteristics of tunnel junctions fabricated on N+Si substrates. Six samples are chosen from an area of ˜1 cm² around the center of the wafer.

FIG. 5 shows I-V characteristics of tunnel junctions fabricated on Si photovoltaic cells (based on P—Si substrates). The peak current densities fall in the same range as the tunnel junctions fabricated on N₊ Si substrates.

### DETAILED DESCRIPTION

Various embodiments and aspects of the disclosure will be described with reference to details discussed below. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosure.

As used herein, the terms, “comprises” and “comprising” are to be construed as being inclusive and open ended, and not exclusive. Specifically, when used in the specification and claims, the terms, “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately” are meant to cover variations that may exist in the upper and lower limits of the ranges of values, such as variations in properties, parameters, and dimensions. In one non-limiting example, the terms “about” and “approximately” mean plus or minus 10 percent or less.

As used herein, the coordinating conjunction “and/or” is meant to be a selection between a logical disjunction and a logical conjunction of the adjacent words, phrases, or clauses. Specifically, the phrase “X and/or Y” is meant to be interpreted as “one or both of X and Y” wherein X and Y are any word, phrase, or clause.

Unless defined otherwise, all technical and scientific terms used herein are intended to have the same meaning as commonly understood to one of ordinary skill in the art. Unless otherwise indicated, such as through context, as used herein, the following terms are intended to have the following meanings:

As used herein, the terms “solar cell”, “photovoltaic cell”, “photovoltaic device”, or “PV device” refer to any article, structure, material or device that can convert light into electrical energy.

As used herein, the terms “III-V materials” or “III-V alloys” refers to the compounds formed by chemical elements from Group III and Group V from the periodic table of elements and can include binary, ternary, quaternary compounds and compounds with higher number of elements from Groups III and V.

As used herein, the terms “II-VI materials” or “II-VI alloys” refers to the compounds formed by chemical elements from Group II and Group VI from the periodic table of elements and can include binary, ternary, quaternary compounds and compounds with higher number of elements from Groups II and VI.

As used herein, the term “junction” or “P-N junction” refers to the part of a semiconductor device where P-type and N-type materials are located adjacent to each other (optionally including an intermediate intrinsic layer). The P-type refers to an extrinsic semiconductor layer in which the conduction occurs via holes while the N-type refers to an extrinsic semiconductor layer in which the conduction occurs via electrons. For example, a P-type silicon layer may be formed with dopants from the Group III elements such as boron, aluminum and gallium. Similarly, an N-type silicon layer may be formed with dopants from the Group V elements such as phosphorus, arsenic and antimony. The term “one conductivity type” refers to either P-type or N-type and the term “opposite conductivity type” refers to N-type or P-type, respectively.

As used herein, the term “dopant layer” refers to a layer which was doped with either N-type or P-type dopants.

As used herein, the term “degenerately doped” refers to a concentration of electrically active dopants that leads to the conduction band being below the Fermi level in an N-type semiconductor, which is indicated herein as N₊₊, or the valence band being above the Fermi level in a P-type semiconductor, which is indicated herein as P₊₊. The term “moderately doped”, as used herein, refers to a doping level that is not degenerately doped and is indicated herein as either N-type or P-type. The term “highly doped” refers to a doping level that is not degenerately doped, but is doped at a higher level than the moderately doped regions (i.e. intermediate between degenerately doped and moderately doped) and is indicated herein as either N₊ or P₊. Typically, degenerately doped semiconductor layers are used for tunnel junction layers, moderately doped semiconductors are used for solar cell absorber layers and highly doped semiconductors are used for solar cell emitter layers. The typical values for degenerate and moderate doping depend strongly on the semiconductor material and operating conditions, such as temperature. For example, in the case of silicon, the typical concentration levels for degenerate doping are above approximately 5×10¹⁹ cm⁻³, for high doping are approximately 5×10¹⁷ cm⁻³ to 5×10¹⁹ cm⁻³ and for moderate doping are approximately 5×10¹⁵ cm⁻³ to 5×10¹⁷ cm⁻³.

As used herein, the term “polarity” refers to either P-type or N-type semiconductor. When one conductivity type refers to an N-type semiconductor, then its opposite polarity refers to a P-type semiconductor. Similarly when one conductivity type refers to a P-type semiconductor, then its opposite polarity refers to an N-type semiconductor.

As used herein, the terms “tandem” and “multi-junction” generally refer to photovoltaic devices having two or more photovoltaic junctions or subcells.

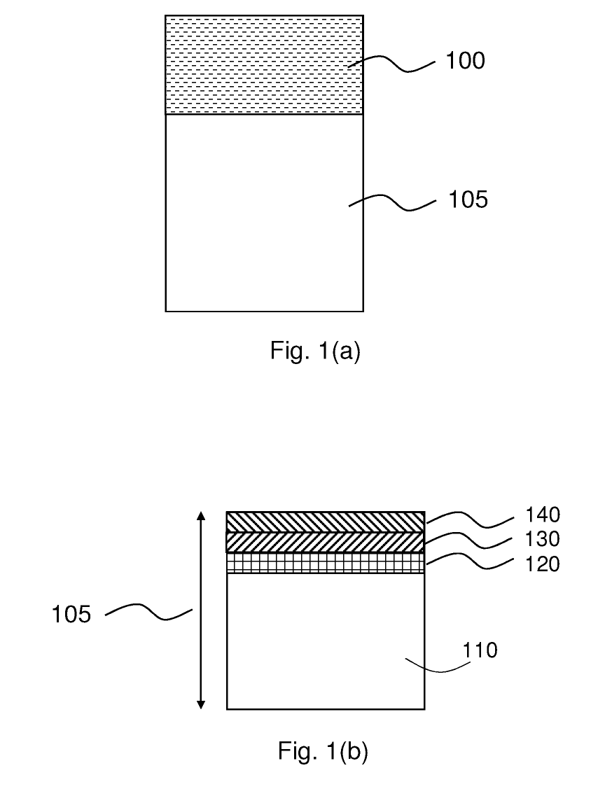

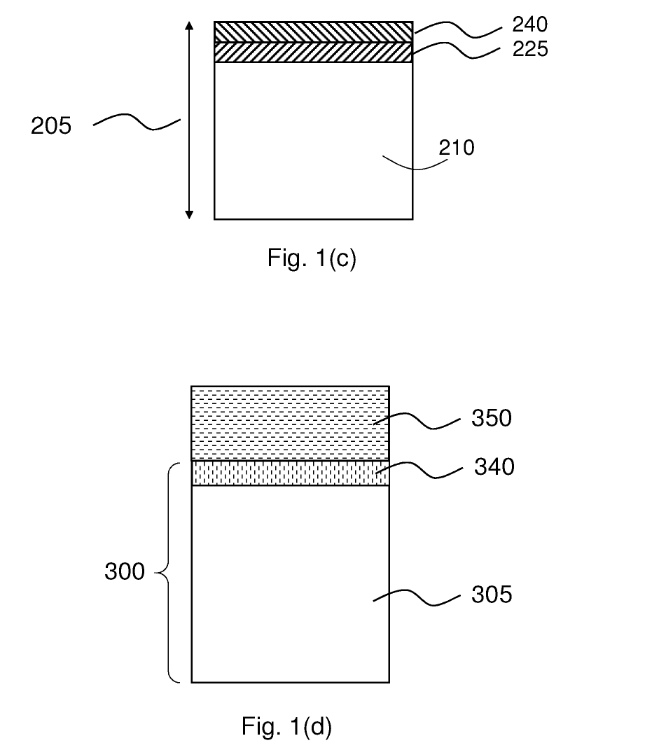

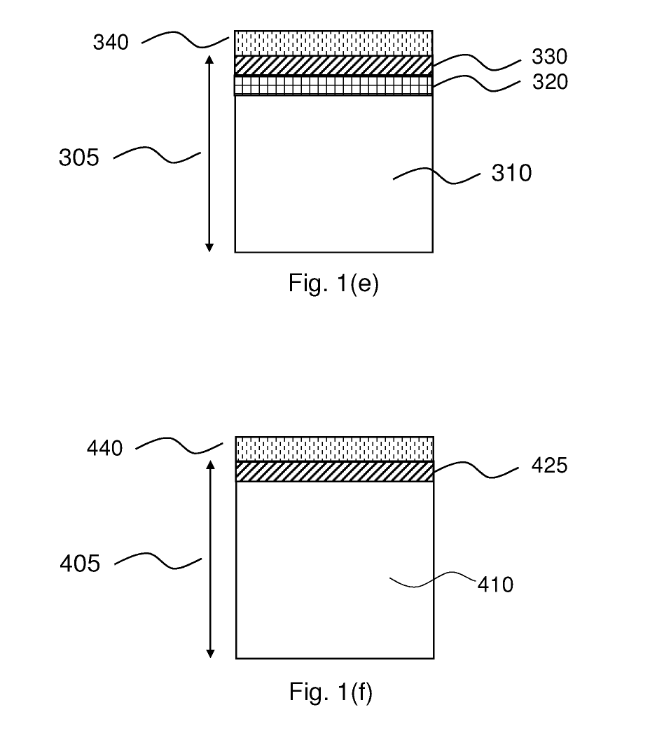

Referring now to FIG. 1, an example embodiment is illustrated in which a substrate 105 is provided as a base structure for building (e.g. fabricating or forming) semiconductor device layers thereon. Substrate 105 includes a photovoltaic homojunction and a silicon-based tunnel junction formed within a silicon substrate. Substrate 105 is amenable for the addition of semiconductor layers 100 thereon.

FIG. 1(b) illustrates, in more detail, the doping structure within the substrate 105. The photovoltaic device homojunction consists of lower section 110 of substrate 105, which serves as the absorber layer, and emitter 120, which are doped with different polarities. The silicon-based tunnel junction consists of two silicon layers, namely lower tunnel junction layer 130 and upper tunnel junction layer 140, which are degenerately doped with different polarities. Lower tunnel junction layer 130 and emitter 120 have the same polarity.

In one example implementation, when the upper tunnel junction layer 140 is P-type, the lower tunnel junction layer 130 is N-type, and emitter 120 is N-type, while lower section 110 of silicon substrate 105 is P-type. The configuration of this example structure, in terms of dopant type and its concentration level, is as follows, from the top tunnel junction layer 140:
1. P₊₊ Si layer (degenerately doped upper tunnel junction layer 140)
2. N₊₊ Si layer (degenerately doped lower tunnel junction layer 130)
3. N₊ Si layer (highly doped emitter layer 120)
4. P-type Si absorber layer (moderately doped lower section 110 of substrate 105).

Similarly, in another example implementation, the polarity of the above structure can be completely reversed, as described below:
1. N₊₊ Si layer (degenerately doped upper tunnel junction layer 140)
2. P₊₊ Si layer (degenerately doped lower tunnel junction layer 130)
3. P₊ Si layer (highly doped emitter layer 120)
4. N-type Si absorber layer (moderately doped lower section 110 of substrate 105) According to one embodiment, the tunnel junction layers are formed via a shallow diffusion process, creating an integrated tunnel junction and solar cell formed within one semiconductor material. The process begins with formation of a solar cell, in this example (and referring to FIG. 1(b)) in a Si substrate 105, having an emitter 120, absorber layer 110, and optional back surface field, by standard methods known to those in the field.

For example, a typical silicon solar cell would include a P-type doped base layer having a nominal resistivity of approximately 1-10 Ω-cm and a thickness of approximately 150-250 μm; and an N-type emitter layer with a doping level in the range of approximately 5×10¹⁷ cm⁻³ to 5×10¹⁹ cm⁻³ and a thickness in the range of approximately 0.1-2.0 μm. Starting with a standard solar cell design has the benefit of utilizing already optimized processes and possibly sharing manufacturing platforms to achieve greater economy in the manufacturing process. The emitter may be formed by standard diffusion or ion implantation processes known to those in the field. The appropriate emitter depth is achieved by control of the ion implantation and thermal annealing processes. By design, the emitter is significantly deeper and less heavily doped than a tunnel junction layer.

The tunnel junction is formed using proximity diffusion doping to achieve very high doping levels with a very shallow depth, by virtue of the thermal diffusion process employed. A dummy wafer of comparable diameter to the Si substrate is prepared as a doping source for the lower N₊₊ tunnel junction layer 130. A spin-on glass containing a high concentration of Phosphorus (for example, approximately 10¹⁹/cm³ to 10²²/cm³) is applied to the dummy wafer using well known spin coating methods and baked at a temperature (for example, approximately 125-375° C.) to remove the carrier solvents. The doping is achieved by placing the dummy wafer in close proximity (e.g. approximately 10 μm-10 mm) to the emitter side of the Si substrate during the annealing process. A rapid thermal cycle may be employed to achieve thin and heavily doped layers. According to one example implementation, a typical ramp cycle would include the following: ramp up (for example, at a rate of approximately 1° C./s to 300° C./s), hold (at approximately 750° C. to 1050° C. for approximately 0-100 s), and ramp down (for example, at a rate of approximately 1° C./s to 300° C./s). During this temperature cycle, the dopants diffuse out of the dummy wafer and into the surface of the silicon wafer.

A second dummy wafer of comparable diameter to the Si substrate is prepared as a doping source for the upper P₊₊ tunnel junction layer 140. A spin-on glass containing a high concentration of Boron (e.g. approximately 10¹⁹/cm³ to 10²²/cm³) is applied to the dummy wafer using well known spin coating methods and baked at a temperature (e.g. approximately 125-375° C.) to remove the carrier solvents. The doping is achieved by placing the dummy wafer in close proximity (for example, 10 μm-10 mm) to the emitter side of the Si substrate during the annealing process. A rapid thermal cycle may be employed to achieve thin heavily doped layers, where a typical ramp cycle would be ramp up (for example, at a rate of approximately 1° C./s to 300° C./s), hold (for example at approximately 750° C. to 1050° C. for 0-100 s) and ramp down (for example, at a rate of approximately 1° C./s to 300° C./s). During this temperature cycle the dopants diffuse out of the dummy wafer and into the surface of the silicon wafer.

The process conditions for the upper and lower tunnel junction layers are controlled (and optionally optimized) such that the doping level in each layer is degenerate, as defined above, which generally requires sufficiently thin doping layers (for example, approximately 10-300 nm) to form tunnel barriers in the range of approximately 1-3 nm.

Furthermore, the process conditions may be controlled (and optionally optimized) such that after the second anneal, the width of the lower tunnel junction layer and the upper tunnel junction layer are approximately equal. The P₊₊ doping will compensate the earlier N₊₊ doping. Therefore, for example, an initial N₊₊ layer of depth 2t and doping concentration n followed by a P₊₊ layer of depth t and doping concentration 2n, will result approximately in an N₊₊ layer of depth t and doping concentration n for the lower tunnel junction layer and a P₊₊ layer of depth t and doping concentration n for the upper tunnel junction layer. It is noted that in the example described above, the P₊₊ dose (2n*t) is approximately equal to the N₊₊ dose (n*2t).

It will be understood that the preceding description provides but one example implementation, and that variations of this process, utilizing other diffusion sources (such as phosphoric acid for Phosphorus doping) and other rapid annealing processes (such as laser annealing), may be employed to achieve similar results. Furthermore, the process may be modified to include one or more additional annealing (thermal processing) steps, for example, in order to further control or modify the dopant concentration profile within one or more layers.

It will be understood that the example implementation involving silicon, as described above, is not intended to limit the present disclosure to silicon-based embodiments, and that the structures and methods may be varied and/or adapted to employ other semiconductor substrates. For example, in one alternative embodiment, substrate 105 may be formed from germanium. Ge is commonly used as both a substrate and as the semiconductor material for the first subcell in the most common triple junction solar design (Ge:InGaAs:InGaP), where the III-V tunnel junction is typically grown on the Ge subcell using epitaxial processes. Therefore, the formation of the first tunnel junction in the Ge substrate by the methods described herein would reduce the number of epitaxial layers required. Similarly, tunnel junctions could be formed in other semiconductor materials available as single crystal substrates, such as Siₓ,Ge₁₋ₓ, GaSb, GaAs, InAs, GaP InP, CdTe, with the proper dopants, doping levels and doping profiles achieved by modifying the process parameters by methods known to workers in the field.

Single crystal substrates may be employed for the bottom cell and tunnel junction formation, due to the higher performance of the solar cell and the uniformity of the material properties of the substrate. By its nature, subsequent lattice-matched growth requires a single crystal substrate. However, lattice-mismatched growth can be achieved on microcrystalline or polycrystalline substrates. For example, the top layer could take the form of semiconductor nanowires (where the lattice matching requirements are relaxed), amorphous materials (where it is not necessary), or layers of varying degrees of crystallinity.

In another example embodiment, lower tunnel junction layer 130 may be combined with emitter layer 110 of FIG. 1(b) into a composite lower tunnel junction layer/emitter, since they are both of the same dopant polarity. In doing so, the doping concentration may be graded by a diffusion process used to introduce the dopants, as described further below, such that the top surface (or portion) of the composite layer is degenerately doped, while the bottom surface (or portion) of the composite layer is highly doped. This embodiment may be beneficial in eliminating one or more processing steps in forming the structure.

Such an embodiment with a composite emitter and lower tunnel junction layer is shown in FIG. 1(c), which illustrates, in more detail, the doping structure within the substrate 205. The photovoltaic homojunction consists of the lower section 210, which serves as the absorber layer and the composite lower tunnel junction layer/emitter 225, which are doped with different polarities. The silicon-based tunnel junction consists of two silicon layers, namely composite lower tunnel junction layer 225 and upper tunnel junction layer 240, which are degenerately doped with different polarities.

In some embodiments, both the upper tunnel junction layer and the upper portion of the lower tunnel junction layer are degenerately doped, as defined above, in order to create a sufficiently thin (for example, less than approximately 3 nm) tunneling barrier, enabling a significant tunneling current. This requires the formation of a thin and highly doped region that is achieved by the thermal diffusion process described herein.

In one example implementation, when upper tunnel junction layer 240 is P-type, composite lower tunnel junction layer/emitter 225 is N-type for the silicon substrate, which is P-type. The example configuration of the structure in terms of dopant type and its concentration level is described as follows, from the top tunnel junction layer 240:
1. P₊₊ Si layer (degenerately doped upper tunnel junction layer 240)
2. N₊₊/N₊ Si layer (degenerately doped composite lower tunnel junction layer/emitter 225)
3. P-type Si absorber layer (moderately doped bottom section 210 of substrate 205)

Similarly, in another example implementation, the polarity of the above structure can be completely reversed as below:
1. N₊₊ Si layer (degenerately doped upper tunnel junction layer 240)
2. P₊₊/P₊ Si layer (degenerately doped composite lower tunnel junction layer/emitter 225)
3. N-type Si absorber layer (moderately doped bottom section 210 of substrate 205)

As described above, in some embodiments, the lower tunnel junction layer may also serve as the solar cell emitter, therefore creating an integrated tunnel junction and solar cell formed from one semiconductor material, without the initial formation of a solar cell. This has the significant benefit of reducing a step from the manufacturing process.

According to one example embodiment, such base structure with an integrated tunnel junction may be fabricated according to a shallow diffusion doping method, as follows. The example process begins, referring to FIG. 1(c), with a Si substrate 205, having an absorber layer 210 and optional back surface field, which may be made according to methods known to those in the field. A typical starting silicon substrate would be doped P-type, with nominal resistivity 1-10 Ω-cm, of 150-250 μm thickness.

A dummy wafer of comparable diameter to the Si substrate is prepared as a doping source for the bottom graded N₊₊/N₊ composite lower tunnel junction layer/emitter 225. A spin-on glass containing a high concentration of Phosphorus (for example, approximately 10¹⁹/cm³ to 10²²/cm³) is applied to the dummy wafer using well known spin coating methods and baked at a temperature (for example, approximately 125-375° C.) to remove the carrier solvents.

The doping is achieved by placing the dummy wafer in close proximity (for example, approximately 10 μm-10 mm) to the top side of the Si substrate during the annealing process. A rapid thermal cycle is employed to achieve thin heavily doped layers, where a typical ramp cycle would be: ramp up (for example, at a rate of approximately 1° C./s to 300° C./s), hold (at approximately 750° C. to 1050° C. for approximately 0-100 s) and ramp down (again at a rate of approximately 1° C./s to 300° C./s). During this temperature cycle the dopants diffuse out of the dummy wafer and into the surface of the silicon wafer.

By virtue of the high doping concentration at the top surface of the lower tunnel junction layer 225, the relatively low doping level of the absorber layer 210 (nominal resistivity 1-10 Ω-cm) and the approximately exponential nature of the decrease in doping level with distance after an anneal process, a graded doping profile is formed. The graded doping profile has the following features: a degenerately doped first portion near the upper surface, with thickness of approximately 10-300 nm, and with the doping profile decreasing rapidly thereafter to a heavy doping second portion having a concentration in the range of approximately 5×10¹⁷ cm⁻³ to 5×10¹⁹ cm⁻³, with a thickness in the range of approximately 0.1-2.0 μm having the features of a typical N-type emitter.

A second dummy wafer of comparable diameter to the Si substrate is prepared as a doping source for the top P₊₊ tunnel junction layer 240. A spin-on glass containing a high concentration of Boron (for example, approximately 10¹⁹/cm³ to 10²²/cm³) is applied to the dummy wafer using well known spin coating methods and baked at a temperature (for example, approximately 125-375° C.) to remove the carrier solvents. The doping is achieved by placing the dummy wafer in close proximity (for example, approximately 10 μm-10 mm) to the top side of the Si substrate during the annealing process. A rapid thermal cycle is required to achieve thin heavily doped layers, where a typical ramp cycle would be ramp up (for example, at a rate of approximately 1° C./s to 300° C./s), hold (for approximately 0-100 s) and ramp down (again, at a rate of approximately 1° C./s to 300° C./s). During this temperature cycle the dopants diffuse out of the dummy wafer and into the surface of the silicon wafer.

In addition to creating a suitable doping profile for the emitter, the process conditions for the upper and lower tunnel junction layers are controlled and optionally optimized such that the doping level is degenerate, as defined above, which generally requires sufficiently thin doping layers (typically 10-300 nm) to form tunnel barriers in the range of 1-3 nm.

Furthermore, the process conditions may be controlled (and optionally optimized) such that after the second anneal, the width of the lower tunnel junction layer (within the composite layer) and the upper tunnel junction layer are approximately equal. The P₊₊ doping will compensate the earlier N₊₊ doping. Therefore, for example, an initial N₊₊ layer of depth 2t and doping concentration n followed by a P₊₊ layer of depth t and doping concentration 2n, will result approximately in an N₊₊ layer of depth t and doping concentration n for the lower tunnel junction layer and a P₊₊ layer of depth t and doping concentration n for the upper tunnel junction layer. It is noted that, as described above, the P₊₊ dose (2n*t) is approximately equal to the N₊₊ dose (n*2t). It is further noted that the N₊ emitter portion of the composite lower tunnel junction layer/emitter 225 will be significantly deeper than the N₊₊ lower tunnel junction layer portion of the composite lower tunnel junction layer/emitter 225, by virtue of the approximately exponential nature of the decrease in doping level with distance as the emitter doping level becomes comparable in magnitude to the moderately doped P-type absorber layer 210.

It will be understood that the preceding description provides but one example implementation of a shallow doping process, and that variations of this process, utilizing other diffusion sources for shallow doping (such as phosphoric acid for Phosphorus doping) and other rapid annealing processes (such as laser annealing) could be employed to achieve similar results.

In another embodiment, a hybrid tunnel junction is contemplated, whereby the lower Si tunnel junction layer is formed in the Si substrate, while the top layer of the tunnel junction is formed by an additive deposition process. As noted above, both the upper and lower layers should be degenerately doped, which may require different doping levels based on their material properties. Various combinations of semiconductors could be contemplated for hybrid tunnel junctions, including, but not limited to Si or Ge as the lower tunnel junction layer and III-V materials, II-VI materials and I-III-V materials for the top tunnel junction layer. The top layer could be formed as a layer of a planar monocrystalline, polycrystalline or amorphous semiconductor material or as a layer of semiconductor nanowires.

FIG. 1(d) shows this embodiment for building semiconductor device layers on a base structure 300. Base structure 300 includes substrate 305, which includes a photovoltaic homojunction and a lower tunnel junction layer (shown in more detail in FIG. 1(e)), and III-V based upper tunnel junction layer 340. The structure is amenable for the addition of semiconductor layers 350 on top of upper tunnel junction layer 340.

FIG. 1(e) illustrates the doping structure within the silicon substrate 305 in more detail. The photovoltaic device homojunction consists of the lower section 310 of the silicon substrate 305, which serves as the absorber layer, and emitter 320, which are doped with different polarities. The silicon-based tunnel junction consists of N-type silicon layer 330 and P-type III-V layer 340, i.e. tunnel junction layers 330 and 340 are degenerately doped layers with different polarities. The lower tunnel junction layer 330 and the emitter 320 formed within substrate 305 have the same polarity.

In one example implementation, when upper tunnel junction layer 340 is P-type, lower tunnel junction layer 330 is N-type, and emitter layer 320 is N-type for a silicon substrate 305 that is P-type. The example configuration of the structure in terms of dopant type and its concentration level is as follows, from the top tunnel junction layer 340:
1. P₊₊ III-V layer (degenerately doped, III-V based upper tunnel junction layer 340)
2. N₊₊ Si layer (degenerately doped lower tunnel junction layer 330)
3. N₊ Si layer (highly doped emitter layer 320)
4. P-type Si absorber layer (moderately doped bottom section 310 of substrate 305)

Similarly, in another embodiment, the polarity of the above structure can be completely reversed such as below:
1. N₊₊ III-V layer (degenerately doped, III-V based upper tunnel junction layer 340)
2. P₊₊ Si layer (degenerately doped lower tunnel junction layer 330)
3. P₊ Si layer (highly doped emitter layer 320)
4. N-type Si absorber layer (moderately doped bottom 310 section of substrate 305)

The top layer of the tunnel junction may be formed on the degenerately doped lower Si tunnel junction layer by an epitaxial growth process after the Si substrate is suitably cleaned and prepared. It will be understood that lattice matched or lattice mismatched growth may be employed to form the top layer of the hybrid tunnel junction, where in the former the lattice constant of the top layer is substantially the same as Si and in the latter it is not. For example, Geisz, et al. (J. F. Geisz, J. M. Olson, D. J. Friedman, K. M. Jones, R. C. Reedy, and M. J. Romero, “Lattice-Matched GaNPAs-on-Silicon Tandem Solar Cells,” in 31^{st} Photovoltaic Specialists Conference, pp. 695-698, 2005) grew GaNPAs solar cell structures on Si that were substantially lattice-matched, whereas Carmody, et al. (M. Carmody, S. Mallick, J. Margetis, R. Kodama, T. Biegala, D. Xu, P. Bechmann, J. W. Garland, and S. Sivananthan, “Single-crystal II-VI on Si single-junction and tandem solar cells,” Applied Physics Letters, 96, 153502, 2010) grew CdZnTe solar cell structures on Si that were lattice-mismatched. The GaNPAs solar cell structures on Si utilized III-V based tunnel junctions, whereas the CdZnTe solar cell structures on Si utilized II-IV based tunnel junctions. In epitaxial growth, the dopants are typically incorporated during the growth process and are typically not added via diffusion or implantation processes after the growth process. It will be understood, however, that any suitable additive deposition process may be employed to form top layer of the hybrid tunnel junction and that any suitable doping method may be employed to dope said layer.

In another embodiment, lower tunnel junction layer 330 and emitter layer 320 of FIG. 1(e) may be combined into a composite lower tunnel junction layer/emitter since they are both of the same dopant polarity. In doing so, the doping concentration may be graded by the diffusion process used to introduce the dopants as described in the preceding related embodiment, such that the top surface (or portion) of the composite layer is degenerately doped, while the bottom surface (or portion) of the composite layer is highly doped. This may be beneficial in eliminating one processing step in forming the structure.

An example of such an embodiment with a composite emitter and lower tunnel junction layer is shown in FIG. 1(f), which illustrates, in more detail, the doping structure within the silicon substrate 405. As shown in the Figure, the photovoltaic homojunction consists of lower section 410 of silicon substrate 405, which serves as the absorber layer and the composite lower tunnel junction layer/emitter 425, which are doped with different polarities. The tunnel junction consists of composite lower tunnel junction layer 425 and III-V based upper tunnel junction layer 440, which are degenerately doped with different polarities.

For example, in one example implementation, when upper tunnel junction layer 440 is P-type, composite lower tunnel junction layer/emitter 425 is N-type for a silicon substrate 405 which is P-type. The example configuration of the example structure, in terms of dopant type and its concentration level, is as follows from the top tunnel junction layer 440:
1. P₊₊ III-V layer (degenerately doped, III-V based upper tunnel junction layer 440)
2. N₊₊/N₊ Si layer (degenerately doped composite lower tunnel junction layer/emitter, 425)
3. P-type Si absorber layer (moderately doped bottom section of substrate 410)

Similarly the polarity of the above structure can be completely reversed as below:
1. N₊₊ III-V layer (degenerately doped, III-V based upper tunnel junction layer 440)
2. P₊₊/P₊ Si layer (degenerately doped composite lower tunnel junction layer/emitter, 425)
3. N-type Si absorber layer (moderately doped bottom section of substrate 410)

In some embodiments, a back surface field (BSF) may be formed via doping of the bottom of the substrate with the same type of polarity as the lower region of the substrate. This could be introduced as an additional step in all of the configurations described above.

When dopants are introduced into a semiconductor substrate, for example from one direction, the resulting concentration of the dopants is not uniform throughout the substrate. Accordingly, when concentrations are recited herein in association with such layers, it will be understood that such concentrations are to represent average concentrations within the region of varying concentration within the substrate, unless otherwise stated.

Furthermore, although the example embodiments provided herein involve simple doping processes for the formation of vertical doping structures, it will be understood that such doping structures could alternatively be formed via a different series of process steps (e.g. potentially involving a smaller number of doping steps) to the same end, and the description herein is thus not intended to preclude those possibilities.

The following examples are presented to enable those skilled in the art to understand and to practice embodiments of the present disclosure. They should not be considered as a limitation on the scope of the disclosure, but merely as being illustrative and representative thereof.

### EXAMPLES

Example photovoltaic devices were fabricated and tested, for which the tunnel junction consisted of degenerately doped P-type and N-type layers formed within a silicon substrate. According to one of the example embodiments described above, the tunnel junction layer that is closer to the silicon substrate was employed as a composite layer, also acting as the emitter, as described above and shown in FIG. 1(c).

As described in further detail below, a spin-on-dopant (SOD) process was employed to form the composite emitter/junction layer via a proximity diffusion doping. A doped layer was formed on a dummy wafer via a spin-on process, and the dummy wafer with the doped layer was placed in close proximity to the front side of a cleaned silicon wafer to transfer dopants into the silicon wafer for the controlled formation of the dopant profile within the composite layer. Hereinafter, the dummy wafer having the SOD layer is referred to as a dopant source wafer, while the cleaned silicon wafer is referred to as a device wafer.

The following example method was employed to form a photovoltaic base structure with an integrated tunnel junction. A 3″ diameter P-type moderately doped silicon device wafer (1-10 Ohm-cm), was oxidized in a UV-Ozone apparatus for 10 minutes in oxygen ambient. The oxide was etched in hydrofluoric (HF) acid of 49% concentration diluted in de-ionized water (DI) with the ratio of 1:10. After rinsing in de-ionized water for 1 minute, the Si wafer was dried with flowing nitrogen gas. Two 3″ diameter dummy wafers were cleaned in the same way and were used as a source of dopants. The spin coating of Emulsitone Phosphorosilicafilm 1×10²¹ on a dummy wafer was applied and baked at 210° C. on a hotplate for 20 minutes to serve as a phosphorus N-dopant source wafer. On the other dummy wafer, the spin coating of Emulsitone Borofilm 100 was applied and baked in the same conditions to serve as a boron P-dopant source wafer.

An N-dopant source wafer was stacked on the top surface of the P-type Si device wafer with 3-4 small silicon or quartz spacers (thickness ˜350 μm) between the two wafers, such that the doping process was performed as a non-contact, proximity-doping process. They were placed on a carbon boat holder and loaded into a Jetfirst (J.I.P. Elec.) rapid thermal annealer (RTA). The temperature cycle was a ramp-up at 30° C./s, annealing at 825° C. for 1 s and a ramp-down at 50° C./s.

Next, the N-dopant source wafer was removed and a P-dopant source wafer was placed underneath the device wafer and annealed at 825° C. for 90 s for the formation of a Back Surface Field (BSF). This step also helped to reduce the surface concentration of the phosphorus dopants and increase the depth of the phosphorus diffusion for a more efficient photovoltaic device emitter. Dilute HF was used to clean the surface of the device wafer before proceeding to the last temperature step: front P₊₊ layer diffusion by a ramp-up at 30° C./s and annealing at 825° C. for 1 s, with a P-dopant source wafer stacked on the top surface of the device wafer.

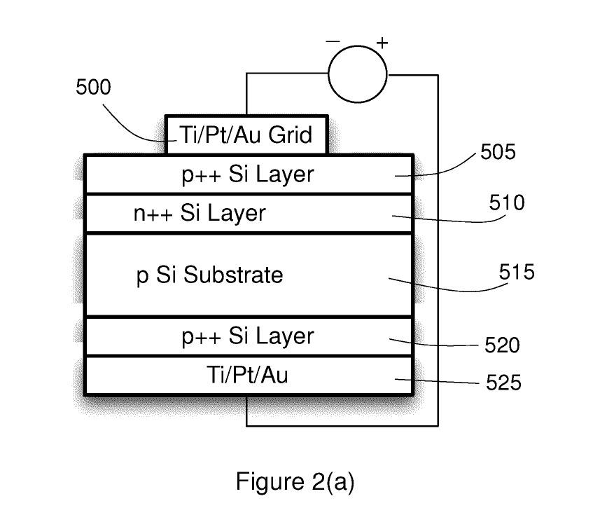

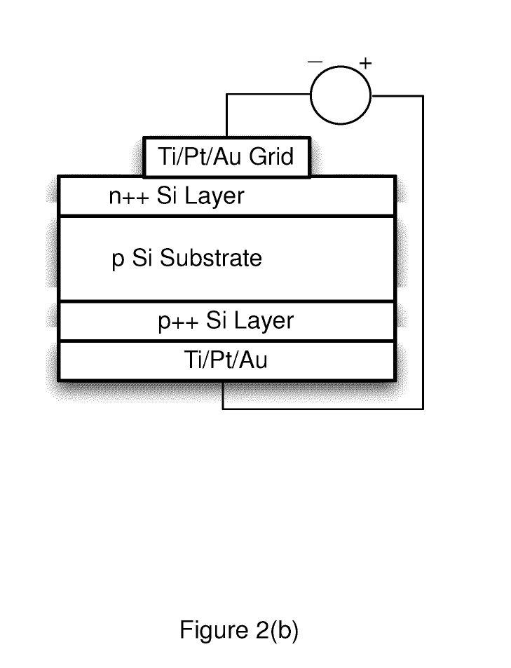

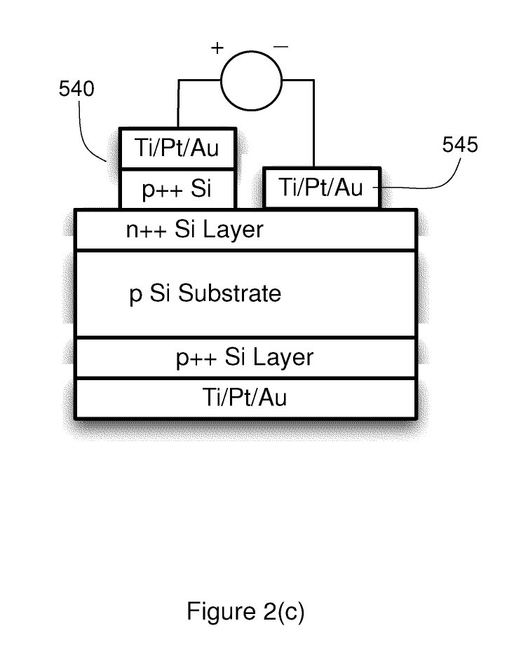

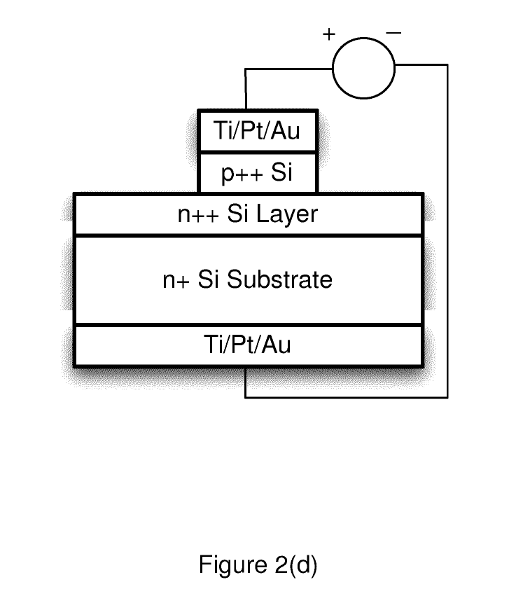

For testing the solar cell characteristics, Ti/Pt/Au was used as the contact metal. The front metal was patterned into grids with less than 10% shadowing. The schematic of the test structure is shown is FIG. 2(a), which includes upper grid contact 500, P₊₊ upper tunnel junction layer 505, N₊₊/N₊ composite lower tunnel junction and emitter layer 510, absorber layer 520, back surface field layer 525, and lower contact 530.

FIG. 2(b) is a photovoltaic device control sample made with the same process but without the top P₊₊ diffusion (i.e. without layer 505 from FIG. 2(a)).

For testing the tunnel junction characteristics, the front metal was patterned into small squares (300×300 μm²) and used as a hard mask for wet etching of the Si P₊₊ layer to provide independent access to both tunnel junction layers. The Si P₊₊ layer was carefully etched down ˜70 nm to expose the N₊₊ layer. As a result, the tunnel junctions were patterned into mesas 540, as shown in FIG. 2(c). Another metal contact 545 was deposited on the N₊₊ layer of the tunnel junction for lateral I-V measurements.

Standalone tunnel junctions grown on highly doped N₊ Si substrates (0.001-0.005 Ohm-cm), as shown in FIG. 2 (d), were fabricated as control samples for measurement of the process.

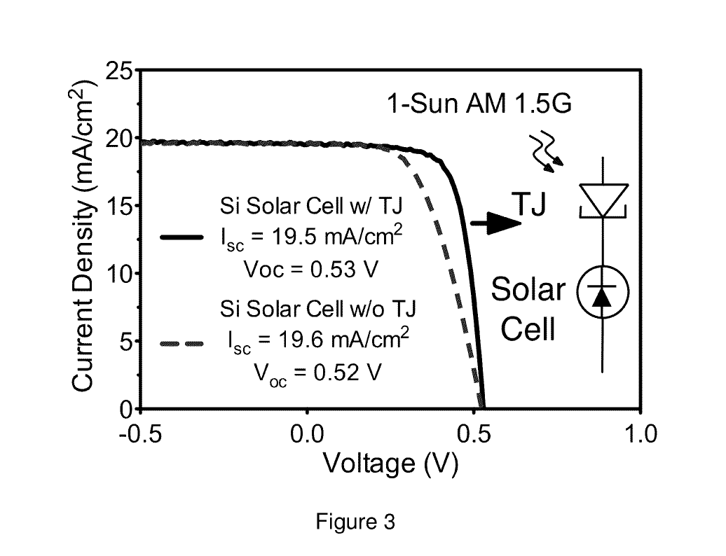

Tunnel junctions in multi-junction photovoltaic devices are designed to provide low resistance Ohmic contact between the subcells and ideally do not negatively impact the photovoltaic device performance. FIG. 3 shows the illuminated I-V characteristics of two photovoltaic devices, one with an integrated tunnel junction (FIG. 2(a)) and one without (FIG. 2(b)). The illuminated cell area is 0.64 cm².

As can be seen from the I-V characteristics, no I_{sc} or V_{oc} reduction is observed, indicating that the solar cell performance is well preserved. Light absorption by the tunnel junction is negligible, due to the very thin tunnel junction/emitter layers resulting from the diffusion process. It is observed that a higher fill factor is obtained for the sample with the integrated tunnel junction, providing clear evidence for its presence.

In the case of the device with the integrated tunnel junction (shown in FIG. 2(a)), the front metal 500 makes contact through the P₊₊ layer 505 of the tunnel junction to the solar cell, instead of directly contacting the N₊₊ composite emitter layer 510. Since Ti/Pt/Au metal makes a better contact with P₊₊ Si than with N₊₊ Si and the tunneling resistance is very low, the contact resistance is lower with the integrated tunnel junction than without, as manifested by the substantially better fill factor. This illustrates that the Si tunnel junction could also be beneficial in enabling the use of more material choices, possibly with better performance, for making contact to a Si solar cell.

The excellent optical transparency and electrical contact to the tunnel junction also indicate that the cleanup of the SOD residues from the Si surface is complete. A clean surface is important for the fabrication of high quality subcells on Si for multi-junction solar cell applications.

The overall performance of the solar cell fabricated by the proximity diffusion method is comparable to cells produced by other common methods, considering that no anti-reflective coating or surface passivation was introduced in the example cell structures. It is noted that when the peak current of the tunnel junction substantially exceeds the short-circuit current of the solar cell, the tunnel junction I-V characteristics are not observable in the light I-V characteristics of the solar cell with the integrated tunnel junction, as in this case with 1 sun illumination used for light I-V testing.

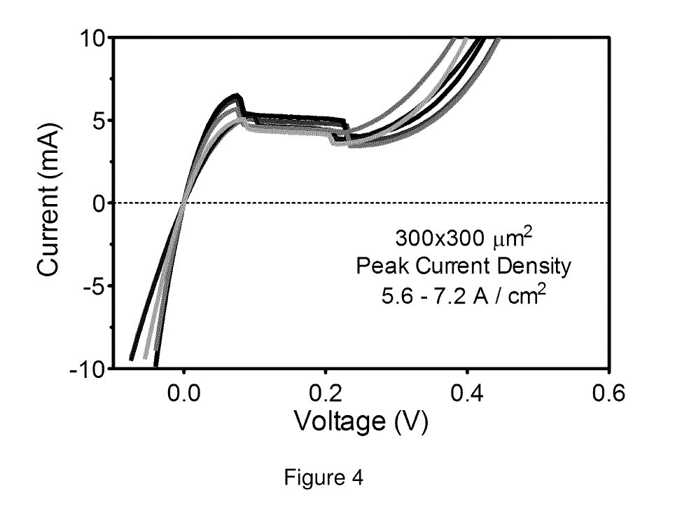

To analyze the performance and uniformity of the tunnel junctions, I-V data were collected from the standalone tunnel junctions of FIG. 2(d). As is shown in FIG. 4, six 300×300 μm² sized sample dots are selected from an area of ˜1 cm² at the center of the wafer. Good uniformity of the tunneling characteristics is observed within this area, with the peak current density measured from the samples ranging from 5.6 to 7.2 A/cm². The process is highly repeatable from wafer to wafer.

For the solar cell (with tunnel junction) shown in FIG. 3, the sample is chosen from a similar area of high uniformity, as determined from the control samples. For multi-junction solar cell applications, the peak current of the tunnel junction is higher than the short-circuit current for normal operation of the solar cell. A peak current density of 5.6 A/cm² allows for operation under at least 250 sun illumination for multi-junction solar cell structures with 1 or more top cells connected to a Si bottom cell. The maximum peak current density obtained is 220 A/cm² from similarly sized samples with a slightly different process condition. This peak current density (if implemented on solar cells) would allow for applications well above 1000 suns.

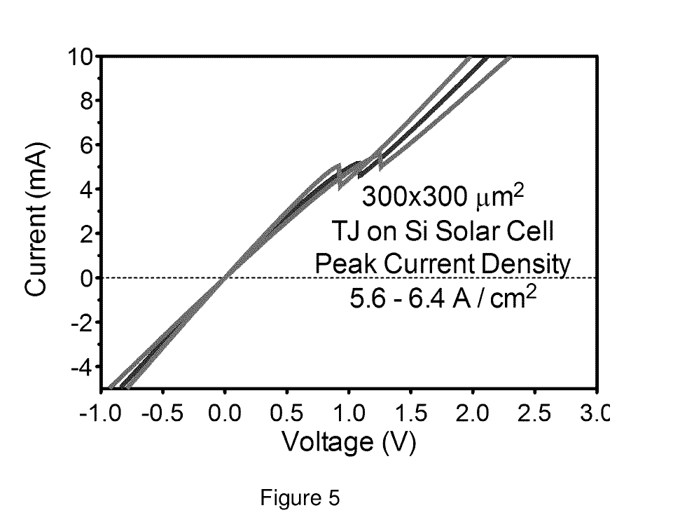

The tunnel junctions integrated on photovoltaic cells through the lateral test structure shown in FIG. 2(c) were also characterized. As shown in FIG. 5, the measured samples exhibited I-V curves with clear negative resistance regions. The peak current densities are in the same range as the control tunnel junctions fabricated on N₊ substrates (FIG. 4), indicating that the tunnel junctions integrated on P-substrate Si photovoltaic devices have comparable performance. The relatively large series resistance seen in FIG. 5 is due to the limitation of the test structure arising from the large lateral resistance between the contact pad on the N₊₊ layer and the bottom of the tunnel junction. The calculated lateral resistance in the test structure is ˜180Ω, arising from conduction through a thin doped layer that is a lateral distance of 100 μm from the edge of the contact pad to the edge of the tunnel junction. In actual multi-junction photovoltaic devices, current conducts vertically and this lateral series resistance would not be seen.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

1. A photovoltaic semiconductor structure, comprising:
a first doped semiconductor layer forming an absorber layer of a first photovoltaic homojunction;
a second doped semiconductor layer having a conductivity type opposite to that of said first doped semiconductor layer, wherein said second semiconductor layer is formed adjacent to said first semiconductor layer, such that said first doped semiconductor layer and said second doped semiconductor layer are formed from a common semiconductor material within a common semiconductor substrate, and wherein said second semiconductor layer comprises a dopant profile with a graded concentration, such that:
a first portion of said second semiconductor layer, distal from said first semiconductor layer, is degenerately doped, thereby forming a first tunnel junction layer of a tunnel junction; and
a second portion of said second semiconductor layer, proximal to said first semiconductor layer, has a dopant concentration suitable for forming an emitter layer of said first photovoltaic homojunction; and
a third doped semiconductor layer having a conductivity type opposite to that of said second doped semiconductor layer, wherein said third doped semiconductor layer is provided adjacent to said second semiconductor layer, and wherein said third semiconductor layer is degenerately doped, thereby forming a second tunnel junction layer of said tunnel junction.

2. The photovoltaic semiconductor structure according to claim 1 wherein first doped semiconductor layer, said second doped semiconductor layer and said third doped semiconductor layer are formed from said common semiconductor material within said common semiconductor substrate.

3. The photovoltaic semiconductor structure according to claim 1 wherein said common semiconductor material is silicon.

4. The photovoltaic semiconductor structure according to claim 1 wherein said common semiconductor material is germanium.

5. The photovoltaic semiconductor structure according to claim 1 wherein said common semiconductor material is selected from the group consisting of SiₓGe₁₋ₓ, GaSb, GaAs, InAs, GaP InP, and CdTe.

6. The photovoltaic semiconductor structure according to claim 1 wherein said third doped semiconductor layer is formed from a semiconductor material that is different from a semiconductor material of said first doped semiconductor layer and said second doped semiconductor layer.

7. The photovoltaic semiconductor structure according to claim 6 wherein said first doped semiconductor layer and said second doped semiconductor layer are formed in silicon.

8. The photovoltaic semiconductor structure according to claim 6 wherein said third doped semiconductor layer is formed from one of a planar monocrystalline semiconductor material, a polycrystalline semiconductor material, an amorphous semiconductor material, and a layer of semiconductor nanowires.

9. The photovoltaic semiconductor structure according to claim 6 wherein said third doped semiconductor layer is formed from one of a group III-V semiconductor material, a group II-VI semiconductor material, and a group I-III-V semiconductor material.

10. The photovoltaic semiconductor structure according to claim 9 wherein the group III-V semiconductor is selected from the group consisting of InGaAs and InGaP.

11. The photovoltaic semiconductor structure according to claim 1 wherein said first portion has a thickness of approximately 10 to 300 nm, and wherein said second portion has a thickness of approximately 0.1 to 2 micrometers.

12. The photovoltaic semiconductor structure according to claim 1 wherein said second portion has an average dopant concentration of approximately 5×10¹⁷ to 5×10¹⁹ cm⁻³.

13. The photovoltaic semiconductor structure according to claim 1 wherein said common semiconductor substrate is a single crystal semiconductor substrate.

14. The photovoltaic semiconductor structure according to claim 1 further comprising one or more additional photovoltaic cells disposed on said second tunnel junction layer.

15. A tandem solar cell device comprising the photovoltaic semiconductor structure according to claim 1.

16. A photovoltaic device comprising the photovoltaic semiconductor structure according to claim 1.

17. A method of forming a photovoltaic semiconductor structure having a composite emitter and tunnel junction layer, the method comprising:
providing a moderately doped semiconductor substrate; and
employing shallow diffusion doping to degenerately dope a region beneath the surface of the semiconductor substrate, such that a composite layer is formed having a conductivity type opposite to that of the moderately doped semiconductor substrate, such that the composite layer comprises:
a first portion proximal to the surface of the semiconductor substrate, the first portion having a degenerately doped concentration suitable for forming a first layer of a tunnel junction; and
a second portion distal from the surface of the semiconductor substrate, the second portion having dopant concentration suitable for forming an emitter layer;
such that a photovoltaic homojunction is formed within the semiconductor substrate.

18. The method according to claim 17 wherein the shallow diffusion doping is accomplished by:
placing a dummy wafer having a dopant concentration in the range of approximately 10¹⁹ to 10²²/cm⁻³ proximal to the semiconductor substrate, without contacting the semiconductor substrate; and
thermal processing the semiconductor substrate by increasing, optionally holding, and subsequently decreasing a temperature of the semiconductor substrate while the dummy wafer is maintained proximal to the semiconductor substrate, such that the first portion and the second portion are formed with a suitable concentration gradient.

19. The method according to claim 18 wherein a gap between the dummy wafer and the semiconductor substrate is between approximately 10 micrometers and 10 mm.

20. The method according to claim 18 wherein a rate of change of the temperature of the semiconductor substrate is between approximately 1 degree Celsius per second and 300 degrees Celsius per second.

21. The method according to claim 17 further comprising:
employing shallow diffusion doping to degenerately dope a region beneath the surface of the semiconductor substrate, such that a second tunnel junction layer is formed beneath the surface of the semiconductor substrate and above the composite layer;
thereby forming a tunnel junction within the semiconductor substrate between the second tunnel junction layer and the first portion of the composite layer.

22. The method according to claim 17 further comprising:
forming a second tunnel junction layer on the semiconductor substrate by an epitaxial or other additive process, wherein the second tunnel junction layer is degenerately doped and has a conductivity type opposite to that of the composite layer, thereby forming a tunnel junction between the second tunnel junction layer and the first portion of the composite layer.

23. A method of forming a photovoltaic semiconductor structure, the method comprising:
providing a semiconductor substrate comprising an absorber layer and an emitter layer having a photovoltaic homojunction formed therebetween, wherein the emitter layer is formed proximal to a surface of the semiconductor substrate;
employing a first shallow diffusion doping step to degenerately dope a region proximal to the surface of the semiconductor substrate, the region having a conductivity type opposite to that of the emitter layer, such that a first tunnel junction layer with a degenerately doped concentration is formed below the surface of the semiconductor substrate; and
employing a second shallow diffusion doping step to degenerately dope a region proximal to the surface of the semiconductor substrate, the region having a conductivity type opposite to that of the first tunnel junction layer, such that a second tunnel junction layer with a degenerately doped concentration is formed below the surface of the semiconductor substrate and above the first tunnel junction layer;
thereby forming a tunnel junction within the semiconductor substrate between the first tunnel junction layer and the second tunnel junction layer.

24. A method of forming a photovoltaic semiconductor structure, the method comprising:
providing a semiconductor substrate comprising an absorber layer and an emitter layer having a photovoltaic homojunction formed therebetween, wherein the emitter layer is formed proximal to a surface of the semiconductor substrate;
employing a first shallow diffusion doping step to degenerately dope a region proximal to the surface of the semiconductor substrate, the region having a conductivity type opposite to that of the emitter layer, such that a first tunnel junction layer with a degenerately doped concentration is formed below the surface of the semiconductor substrate; and
forming a second tunnel junction layer on the semiconductor substrate by an epitaxial or other additive process, wherein the second tunnel junction layer is degenerately doped and has a conductivity type opposite to that of the first tunnel junction layer;
thereby forming a tunnel junction between the first tunnel junction layer and the second tunnel junction layer.
